(19) United States
(12) Patent Application Publication
(10) Pub. No.: US 2013/0193489 A1
(43) Pub. Date: Aug. 1, 2013

(54) INTEGRATED CIRCUITS INCLUDING COPPER LOCAL INTERCONNECTS AND METHODS FOR THE MANUFACTURE THEREOF

(71) Applicants: Peter Baars, Dresden (DE); Erik P. Geiss, Dresden (DE)

(72) Inventors: Peter Baars, Dresden (DE); Erik P. Geiss, Dresden (DE)

(73) Assignee: GLOBALFOUNDRIES INC., Grand Cayman (KY)

(21) Appl. No.: 13/361,644

(22) Filed: Jan. 30, 2012

(51) Int. Cl. H01L 21/768; H01L 23/48

(52) U.S. Cl. 257/213; 438/648; 438/618; 257/741; 257/E21.59; 257/E21.585; 257/E23.011

(57) ABSTRACT

Embodiments of a method for manufacturing an integrated circuit are provided. In one embodiment, a partially-fabricated integrated circuit is produced including a semiconductor substrate having source/drain regions, and a plurality of transistors including a plurality of gate conductors formed over the semiconductor substrate and between the source/drain regions. Device-level contacts are formed in ohmic contact with the gate conductors and with the source/drain regions. The device-level contacts terminate at substantially the same level above the semiconductor substrate. Copper interconnect lines are then formed in a level above the device-level contacts and in ohmic contact therewith to locally interconnect the plurality of transistors.

### TECHNICAL FIELD

The present invention relates generally to integrated circuits and, more particularly, to integrated circuits, such as high density static random access memory cells, having low resistance copper local interconnects, as well as to methods for the manufacture thereof.

### BACKGROUND

During front end-of-the-line processing, a plurality of semiconductor devices (e.g., transistors, resistors, capacitors, and the like) are formed on a semiconductor wafer. The semiconductor devices are then locally interconnected during middle-of-the-line (MEOL) processing to produce an integrated circuit, such as a logic circuit or a memory cell. To enable the local interconnection of the semiconductor devices during MEOL processing, device-level plugs are formed in ohmic contact with the electrically-active areas of the substrate (commonly designated as “RX”) and the gate conductors (commonly designated as “PC”), and local interconnect lines are formed in ohmic contact with the device-level plugs. In many cases, such as in certain replacement gate-based processes, the local interconnect lines and device-level plugs can be divided into three general categories: (i) trench-with-late-silicide contacts (referred to herein as “TS contacts”) in ohmic contact with RX; (ii) local interconnect lines (referred to herein as “CA contacts”) in ohmic contact with the TS contacts; and (iii) plugs in ohmic contact with PC (referred to herein as “CB contacts”). The TS, CA, and CB contacts are collectively referred to herein as the “local contacts.” The local contacts may also include shared TS/CB contacts, which provide an electrically-bridged connection to both RX and PC. After formation of the local contacts, the fabrication process advances to back end-of-the-line (BEOL) processing during which additional BEOL layers are formed to globally interconnect the integrated circuits, which are subsequently separated into individual die during wafer dicing.

From one circuit generation or node to the next, critical dimensions are continually reduced and pattern densities are continually increased. To enable the production of highly dense circuit layouts, MEOL patterning processes have been developed wherein multiple masks are utilized to pattern the dielectric layers deposited over the semiconductor devices (e.g., the pre-metal dielectric layer and the overlying intermetal dielectric layer), which are subsequently filled with metal and polished to produce the local contacts. The CA contacts may thus be printed with a first mask and a first illumination source, while the CB contacts are printed with a second mask and a second illumination source. To achieve an extremely fine resolution, the CA contacts may be printed to have a unidirectional orientation; that is, the CA contacts may be printed as small trench-like structures, which are elongated along the maximum axis of the circuit layout, but extremely narrow along the minimum axis. The CB contacts, however, are typically not so constrained and may be printed to have a bidirectional orientation; that is, the CB contacts may extend along both the maximum and minimum axes of the circuit layout.

In densely-patterned circuits, such as SRAM cells included within semiconductor nodes equal to or less than 20 nanometers (“nm”), geometry-driven design rules may exclude the usage of copper in the metallization of contact levels containing non-unidirectional local contacts. In the case of conventionally-produced circuits of the type described above, the bidirectional CB contacts typically extend downward through the local interconnect level in which the CA contacts are formed and into an upper portion of the device-contact level in which the TS contacts are formed. Design rules may consequently prohibit the usage of a common copper fill to metalize both the CA and CB contacts. Tungsten, which is generally associated with less restrictive design rules, is commonly utilized in place of copper. However, the electrical resistance of tungsten is higher than that of copper; consequently, the usage of tungsten in the place of copper results in direct penalties against device performance.

There thus exists an ongoing need to provide embodiments of a method for fabricating a high density integrated circuit, such as an SRAM cell, enabling the usage of copper in the formation of local interconnect lines (CA contacts) to improve overall device performance. Ideally, embodiments of such a method would also enable the formation of a low-resistance connection between the local interconnect lines and the conductive plugs (TS contacts) formed in contact with the electrically-active areas of the substrate (RX). It would also be desirable to provide embodiments of an integrated circuit produced pursuant to such a method. Other desirable features and characteristics of the present invention will become apparent from the subsequent detailed description and the appended Claims, taken in conjunction with the accompanying Drawings and the foregoing Technical Field and Background.

### BRIEF SUMMARY

Embodiments of a method for manufacturing an integrated circuit are provided. In one embodiment, a partially-fabricated integrated circuit is produced including a semiconductor substrate having source/drain regions, and a plurality of transistors including a plurality of gate conductors formed over the semiconductor substrate and between the source/drain regions. Device-level contacts are formed in ohmic contact with the gate conductors and with the source/drain regions. The device-level contacts terminate at substantially the same level above the semiconductor substrate. Copper interconnect lines are then formed in a level above the device-level contacts and in ohmic contact therewith to locally interconnect the plurality of transistors.

Embodiment of an integrated circuit are further provided. In one embodiment, the integrated circuit includes a semiconductor substrate having a plurality of source/drain regions, a plurality of gate conductors formed over the semiconductor substrate, a plurality of device-level contacts in ohmic contact with the gate conductors and with the source/drain regions, and copper interconnect lines in a level above the device-level contacts and in ohmic contact therewith to locally interconnect the plurality of transistors. The device-level contacts terminate at substantially the same level above the semiconductor substrate.

### BRIEF DESCRIPTION OF THE DRAWINGS

The present invention will hereinafter be described in conjunction with the following drawing figures, wherein like numerals denote like elements, and wherein:

FIG. 1 is a simplified cross-sectional view of a high density integrated circuit (partially shown) including a plurality of transistors locally interconnected, in part, by a series of tungsten interconnect lines, as illustrated in accordance with the teaching of prior art; and

FIGS. 2-14 are simplified cross-sectional views of a high density integrated circuit (partially shown) at various stage of completion and including a plurality of transistors locally interconnected, in part, by a series of copper interconnect lines, as illustrated in accordance with an exemplary and non-limiting embodiment of the present invention.

### DETAILED DESCRIPTION

The following Detailed Description is merely exemplary in nature and is not intended to limit the invention or the application and uses of the invention. Furthermore, there is no intention to be bound by any expressed or implied theory presented in the preceding Technical Field, Background, Brief Summary, or the following Detailed Description. Various steps in the manufacture of integrated circuits are well-known and so, in the interest of concision, many conventional steps will only be mentioned briefly herein or will be omitted entirely without providing the well-known process details. As appearing herein, the term “over” is utilized to indicate relative position between two structural elements and not necessarily to denote physical contact between structural elements. Terms of orientation or direction, such as “vertical,” “horizontal,” “upper,” “lower,” “above,” and “below,” are also utilized below in describing one or more exemplary embodiments in conjunction with the accompanying Drawings. Such terms of direction and orientation are utilized for the purpose of description only and should not be construed as limiting the scope of the accompanying Claims.

FIG. 1 is a simplified cross-sectional view of a portion of a partially-completed integrated circuit 20 illustrated in accordance with the teachings of prior art. Integrated circuit 20 is densely patterned and may be, for example, an SRAM cell included within 20 nm a semiconductor node or below. Integrated circuit 20 includes a plurality of transistors 22 formed over a semiconductor substrate 24 (e.g., a bulk silicon wafer or a silicon-on-insulator wafer) having a plurality of electrically-active source/drain (“S/D”) regions 28 (RX). Each transistor 22 includes a gate conductors 26 (PC), which can be a layer of polycrystalline silicon, a metal, a conductive work function-determining material, or a combination of these materials. Gate conductors 26 (PC) are laterally interspersed with S/D regions 28 (RX). Transistors 22 further include various other structural features and elements, such as sidewall spacers formed adjacent gate conductors 26 (PC) and an underlying channel region; however, such features are well-known and are not shown in FIG. 1 for clarity. A pre-metal dielectric (“PMD”) layer 30 (or first ILD layer) overlies semiconductor substrate 24 and envelopes or surrounds gate conductors 26 (PC); and an interlevel dielectric (“ILD”) layer 32 is formed over PMD layer 30. Bodies of gap fill material 34 may be embedded within PMD layer 30 between gate conductors 26 (PC) and above S/D regions 28 (RX) as a result of previously-performed FEOL processing steps (e.g., removal of polysilicon dummy gates and subsequent oxide fill).

During MEOL processing, local contacts are formed within PMD layer 30 and ILD layer 32 to locally interconnect gate conductors 26 (PC) and S/D regions 28 (RX). Three different types of local contacts are included in the portion of integrated circuit 20 shown in FIG. 1: (i) trench-with-late-silicide plugs 36 (referred to herein as “TS contacts 36”), which extend through PMD layer 30 to contact silicide contact points 37 formed within S/D regions 28 (RX); (ii) local interconnect lines 38 (referred to here as “CA contacts 38”), which extend through ILD layer 32 to contact TS contacts 36; and (iii) electrically-conductive plugs 40 (referred to herein as “CB contacts 40”), which extend through ILD layer 32 and a portion of PMD layer 30 to contact gate conductors 26 (PC). As further indicated in FIG. 1, in embodiments wherein integrated circuit 20 is an SRAM cell, CA contact 38(b) and CB contact 40(b) may be integrally formed in mutual ohmic contact to create an electrically-bridged or shared contact 38(b), 40(b) to gate conductor 26(c) and silicide contact point 37(b) of S/D region 28(b). TS contacts 36 are commonly fabricated to have relatively narrow widths (e.g., each contact 36 may have a width of about 25 nm in the case of a 20 nm semiconductor node) to decrease the likelihood of shorting to neighboring gate conductors 26; consequently, relatively precise alignment between TS contact 36(a) and the overlying CA contact 38(a) is generally required to ensure the creation of a low resistance electrical connection across this contact-to-contact interface.

In one common fabrication process, TS contacts 36 are initially produced within PMD layer 30 utilizing a first series of lithographic patterning and metallization steps; e.g., lithographic patterning, etching, metal fill, and removal of the metal overburden via chemical mechanical planarization (“CMP”) polishing. ILD layer 32 is then deposited over PMD layer 30 and TS contacts 36; and CA contacts 38 and CB contacts 40 are subsequently produced utilizing a second series of lithographic patterning and metallization steps. To achieve a significant reduction in critical dimensions along the minor axis of the circuit layout (the horizontal axis in the orientation show in FIG. 1), the illumination source utilized to print the CA contacts 38 may be optimized in a manner that requires contacts 38 to have a unidirectional orientation. That is, all CA contacts 38 may extend in parallel directions or, stated differently, the longitudinal axes of CA contacts 38 may be substantially parallel with one another and with the maximum axis of the circuit layout. In contrast, CB contacts 40 may be printed to have a non-unidirectional orientation; e.g., CB contacts 40 may be printed to have a bidirectional orientation such that the longitudinal axes of certain CB contacts 40 are substantially parallel to the maximum axis of the circuit layout, while the longitudinal axes of other contacts 40 are substantially parallel to the minimum axis of the circuit layout.

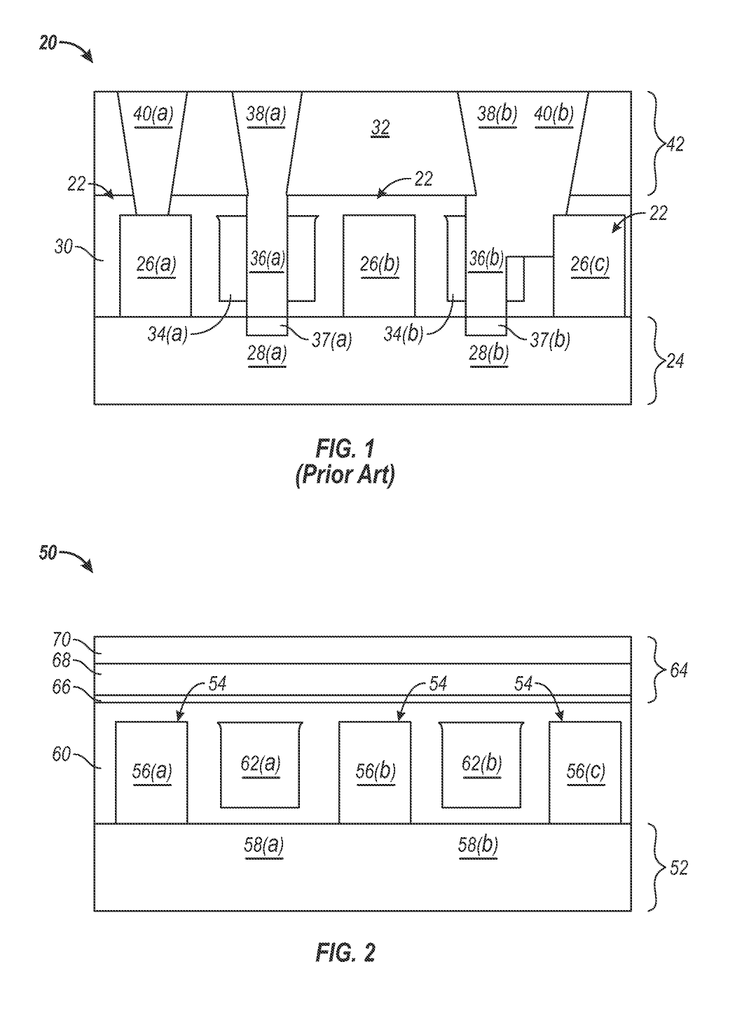

It can be seen in FIG. 1 that CB contacts 40 extend across the level in which CA contacts 38 are formed (referred to herein as the “local interconnect level” and identified in FIG. 1 by bracket 42). Stated differently, CB contacts 40 overlap in elevation range with CA contacts 38, as taken along an axis orthogonal to the upper surface of semiconductor substrate 24. Due, at least in part, to the non-unidirectional orientation of CB contacts 40 in combination with unidirectional CA contacts 38, local interconnect level 42 is imparted with an especially high pattern density. As explained in the foregoing section entitled “BACKGROUND,” geometry-driven design rules may prohibit the usage of copper in the filling of bidirectional local contacts in the case of such a densely-patterned circuit. The exceptionally high density of local interconnect level 42 may thus prohibit the common copper fill of CA and CB contacts 38 and 40 during MEOL processing. While tungsten can be utilized to fill CA and CB contacts 38 and 40, the electrical resistance of tungsten is higher than that of copper and consequently detracts from overall performance of integrated circuit 20, when completed. To overcome this limitation, an exemplary embodiment of a method for manufacturing an SRAM cell or other densely-patterned integrated circuit is described below in conjunction with FIGS. 2-14 wherein the CA contacts and CB contacts are formed on discrete, non-overlapping levels (as taken through thickness of the circuit) to decrease the pattern density of the local interconnect level and thereby enable copper fill of the local interconnect lines (CA).

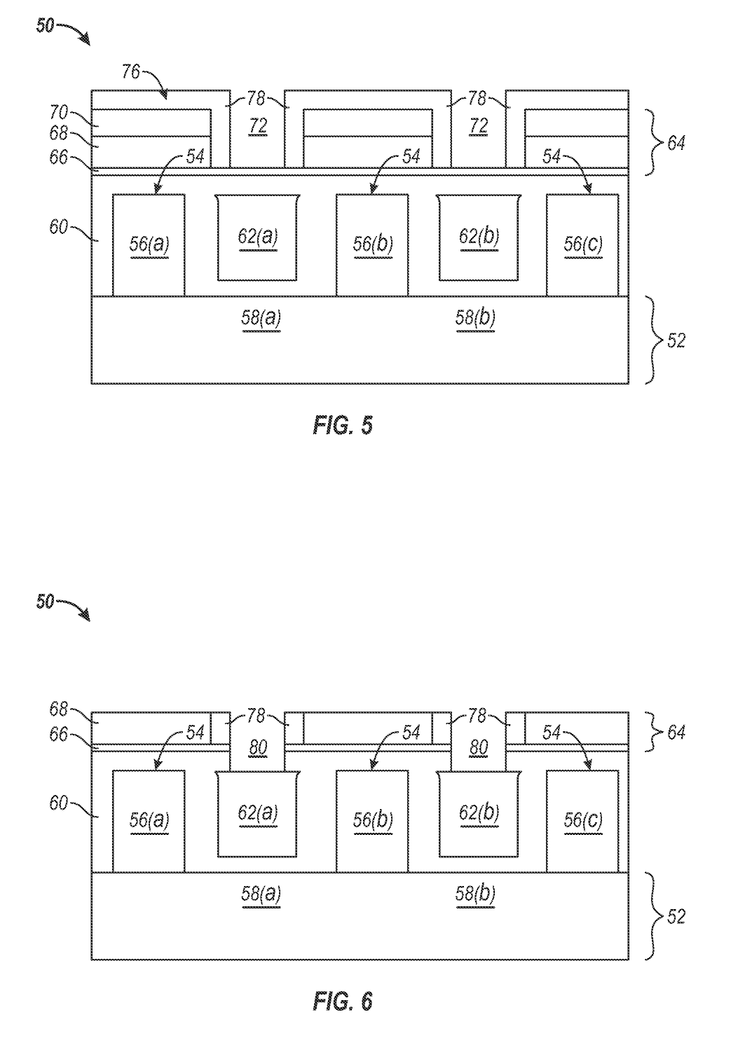

FIGS. 2-14 are simplified cross-sectional views of an integrated circuit 50 (partially shown) at various stage of completion and illustrated in accordance with an exemplary embodiment of the present invention. Integrated circuit 50 may be, for example, a densely-patterned SRAM cell included within a semiconductor node equal to or less than 20 nm. Referring initially to the simplified cross-sectional view shown in FIG. 2, integrated circuit 50 includes a semiconductor substrate 52 (e.g., a bulk silicon wafer or a silicon-on-insulator wafer) over which a plurality of transistors 54 has been formed. Transistors 54 are generically illustrated in FIGS. 2-14 as including a plurality of gate conductors 56 (PC) and a plurality of electrically-active substrate regions or S/D regions 58 (RX), which are interspersed with gate conductors 26. Transistors 54, and more generally integrated circuit 20, will further include other commonly-known structural elements and features that are not shown in FIG. 1 for clarity (e.g., sidewall spacers, channel regions, electrical isolation features, etc.). A pre-metal dielectric (“PMD”) layer 60 (or first ILD layer) overlies semiconductor substrate 52, gate conductors 56 (PC), and S/D regions 58 (RX), and envelops or surrounds conductors 56 (PC). Bodies of a gap fill material 62 may be embedded within PMD layer 60 between gate conductors 56 (PC) as a result of previously-performed FEOL processing steps. In accordance with embodiments of the present invention, gap fill bodies 62 may be usefully employed as etch stop features during patterning of PMD layer 60 and the formation of the TS trenches, as described more fully below in conjunction with FIG. 6. In one implementation, PMD layer 60 is composed of a gap fill nitride, while embedded gap fill bodies 62 are composed of a gap fill oxide.

A multi-layer capping or mask stack 64 is formed over PMD layer 60. In the exemplary embodiment illustrated in FIG. 2, mask stack 64 includes three layers: (i) an etch stop layer 66 formed over PMD layer 60; (ii) a first capping layer 68 formed over etch stop layer 66; and (iii) and a second capping layer 70 formed over capping layer 68. First capping layer 68 is preferably (although not necessarily) formed from a nitride and will consequently be referred to hereafter as “nitride capping layer 68.” By contrast, second capping layer 70 is preferably (although not necessarily) formed from an oxide and will consequently be referred to hereafter as “oxide capping layer 70.” Although layer 66 can be formed from other materials, such as titanium nitride, etch stop layer 66 is preferably formed from a high-k dielectric material; i.e., a material having a dielectric constant higher than that of silicon dioxide or silicon oxynitride. A non-exhaustive list of suitable high-k dielectric materials includes hafnium dioxide, hafnium silicon oxide, titanium dioxide, tantalum pentoxide, and zirconium dioxide. Deposition techniques suitable for usage in the formation of etch stop layer 66, as well as in the formation of capping layers 68 and 70, include chemical vapor deposition (CVD), low pressure chemical vapor deposition (LPCVD), sub-atmospheric chemical vapor deposition (SACVD), and plasma enhanced chemical vapor deposition (PECVD). In embodiments wherein layer 66 is formed from a high-k dielectric material, etch stop layer 66 is conveniently deposited to a thickness less than about 5 nm and preferably to a thickness less than about 3 nm. By comparison, nitride capping layer 68 and oxide capping layer 70 may each be deposited to a thickness of about 20 nm. In contrast to certain conventionally-known mask stacks, mask stack 64 does not include a titanium nitride hardmask layer in preferred embodiments.

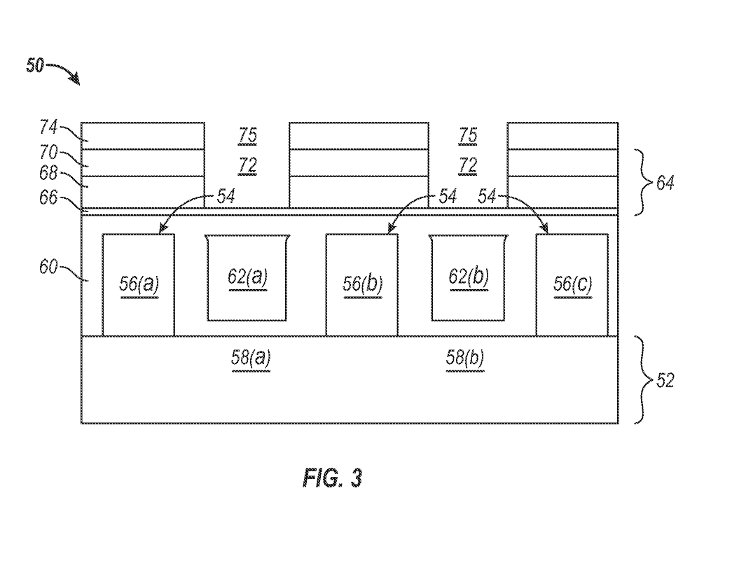

A first lithographical patterning and etching process is performed to create etch mask openings 72 within capping layers 68 and 70 of tri-layer mask stack 64, as generally shown in FIG. 3. Etch mask openings 72 are formed within mask stack 64 at locations generally aligning with embedded gap fill bodies 62 and S/D regions 58, as taken along an axis substantially orthogonal to semiconductor substrate 52 or, stated differently, as taken through the thickness of circuit 50. At this juncture in the fabrication process, etch mask openings 72 extend to, but do not yet penetrate, hard mask layer 68. To produce openings 72 within mask stack 64, a lithographical stack 74 may first be deposited over the upper surface of stack 64. Lithographical stack 74 may then be exposed to an image pattern and treated with a developing solution to form pattern openings 75 within stack 74. An anisotropic dry etch, such as a reactive ion etch, can then be performed utilizing one or more selective chemistries to etch the exposed areas of oxide capping layer 70 and nitride capping layer 68 and thereby create corresponding etch mask openings 72; e.g., a C₄F₆/O₂ chemistry may be utilized in etching of oxide capping layer 70, while a CHF₃/O₂ mixture can be utilized in the etching of nitride capping layer 68.

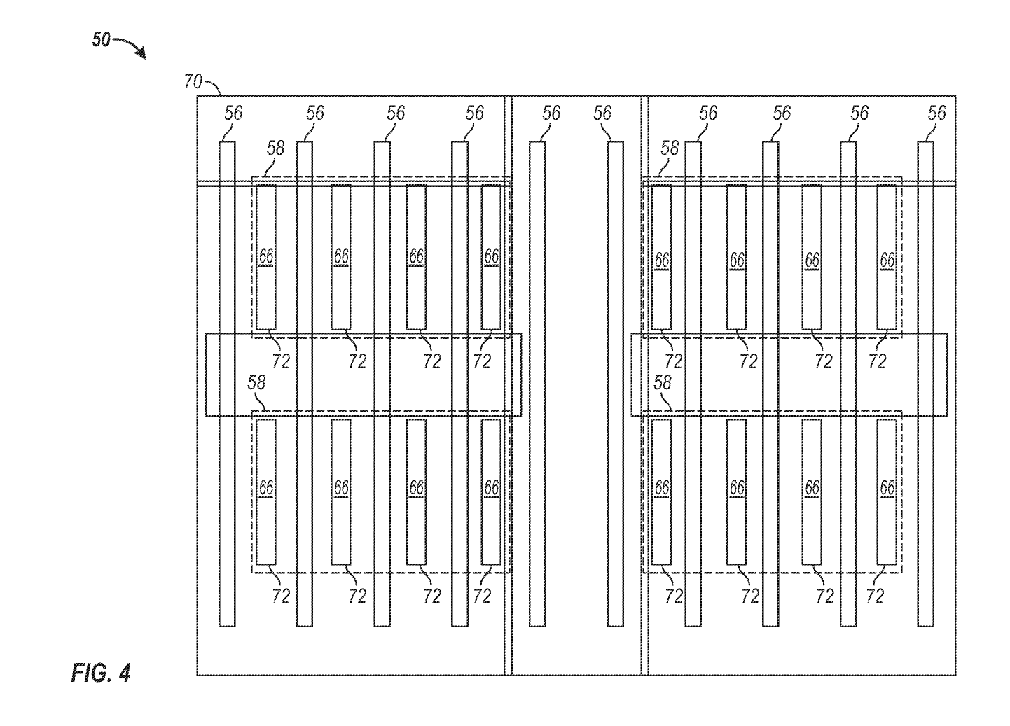

Although illustrated as a single layer in FIG. 3 for simplicity, it will be appreciated that lithographical stack 74 will typically include two or more layers. For example, in certain embodiments, a tri-layer lithographical stack may be utilized including a photoresist layer, an optical planarization layer (“OPL”), and an anti-reflective coating (“ARC”) layer. In this case, the photoresist layer may first be lithographically patterned, a first etch may then be performed to transfer the pattern to the underlying ARC and OPL layers, and then one or more additional etches may be performed to transfer the pattern from the ARC and OPL layers to oxide capping layer 70 and nitride capping layer 68. Any remaining portion of the lithographical stack (e.g., the optical planarization layer) may then be stripped by ashing to yield the final structure shown in FIG. 4 (described below).

FIG. 4 is a top-down or layout view of a portion of integrated circuit 50 after patterning of capping layers 68 and 70 and removal of lithographical stack 74. To provide a convenient frame of reference, gate conductors 56 and S/D regions 58 are shown in FIG. 4; however, it will be noted that mask stack 64 and PMD layer 60 overlay, and thus cover, conductors 56 and regions 58 at this juncture in the fabrication process. Referring collectively to FIGS. 3 and 4, and as can be seen most readily in FIG. 4, etch mask openings 72 are formed to have a long hole pattern wherein each trench 72 has an increased width and a decreased length as compared to the openings of a conventional grid-type mask pattern. By way of non-limiting example, in the case of a 20 nm semiconductor node, etch mask openings 72 may be formed to each have width between about 40 and about 65 nm and, preferably, between about 60 and about 65 nm. Notably, and as will be described more fully below in conjunction with FIGS. 5 and 6, the widths of openings 72 may be further narrowed during fabrication and, thus, need not be tailored to meet minimum critical dimensions at this step in the fabrication process. The length, and thus the length-to-width aspect ratio, of etch mask openings 72 will vary depending upon circuit layout; however, in many cases, openings 72 will each have a length of at least about 300 nm and a length-to-width ratio of at least about 5:1. Openings 72 are unidirectional; that is, the longitudinal axes of all openings 72 are generally parallel with one another and with the maximum axis of the circuit layout. In the illustrated example, etch mask openings 72 are also formed to be parallel with gate conductors 56; to be interspersed with conductors 56, as taken through the thickness of circuit 50 (i.e., along an axis extending into the page in FIG. 4); and to each have a length less than the one half the length of conductors 56.

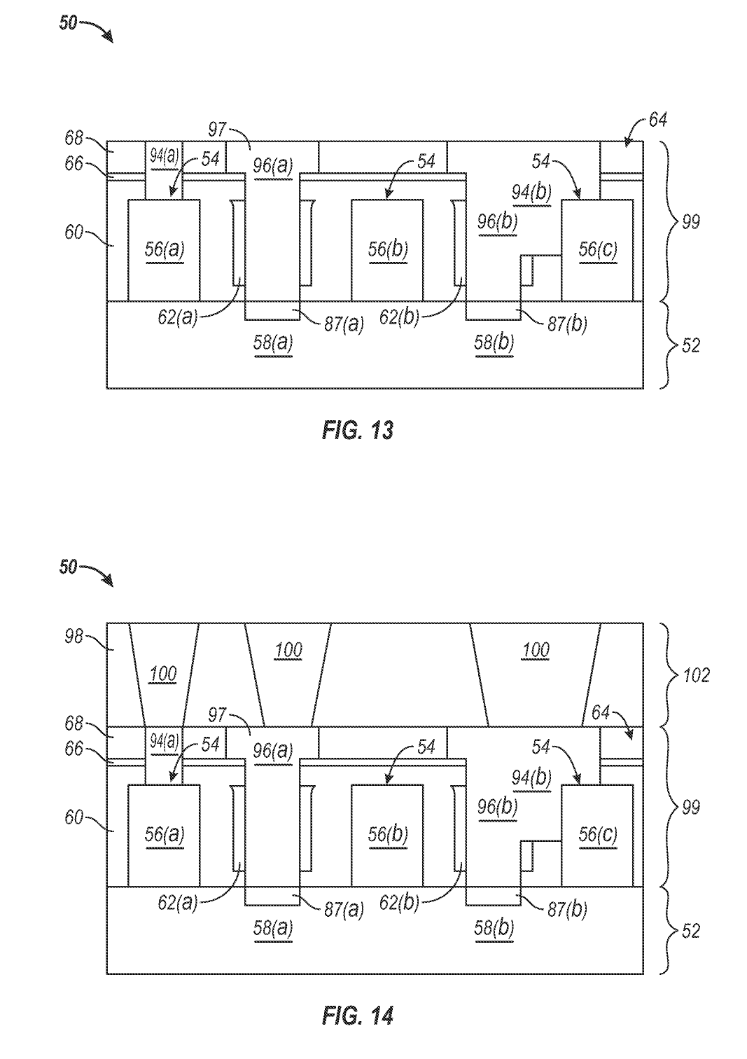

Referring next to FIG. 5, a spacer-forming layer 76 is deposited over mask stack 64 and into etch mask openings 72. In one embodiment, spacer-forming layer 76 is created via the deposition of a low temperature oxide utilizing an atomic layer deposition process. After deposition, the spacer-forming material may then be anisotropically etched utilizing an appropriate chemistry; e.g., if spacer-forming layer 76 is formed from a low temperature oxide, a reactive ion etching (RIE) technique may be performed employing a CH_{X}F_{Y}/O₂/Ar chemistry. As illustrated in FIG. 6, this results in the removal of the bulk of spacer-forming layer 76 and entirety of oxide capping layer 70 and the production of mask opening sidewall spacers 78 adjacent the sidewall surfaces of mask stack 64 defining openings 72. Sidewall spacers 78 extend laterally inward or encroach laterally into openings 72 to decrease the widths thereof. As the deposition process utilized to deposit spacer-forming layer 76 is highly controllable, sidewall spacers 78 allow the precise narrowing etch mask openings 72 to fine tune the widths of openings 72 and thereby achieve a reduction in critical dimensions of the subsequently-formed TS contacts (described below in conjunction with FIGS. 13 and 14). In embodiments wherein integrated circuit 50 is an SRAM cell in a 20 nm semiconductor node, mask opening sidewall spacers 78 may each be formed to have a width of about 20 nm to such that each etch mask trench 72 is imparted with a final narrowed width between about 20 to about 25 nm and, preferably, a final narrowed width equal to about 20 nm.

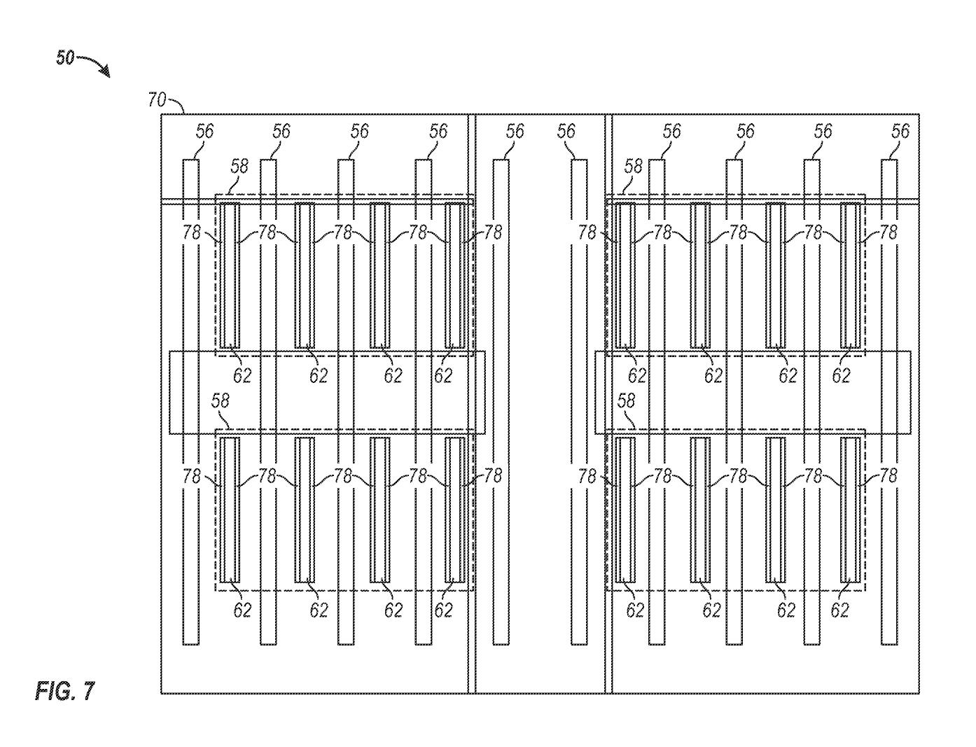

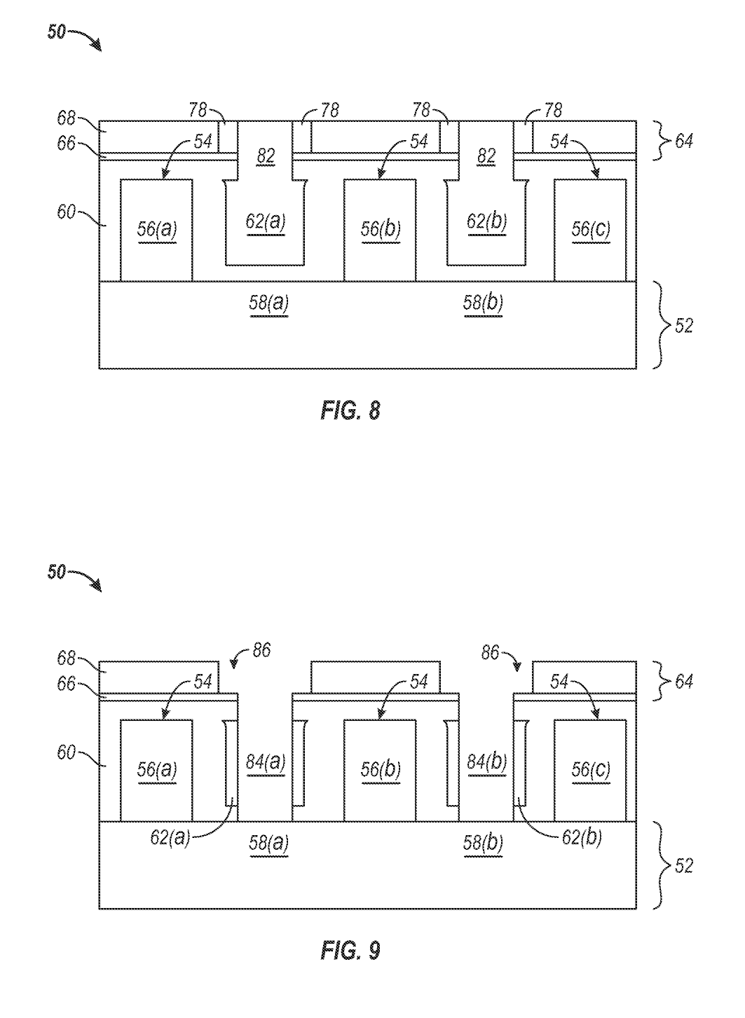

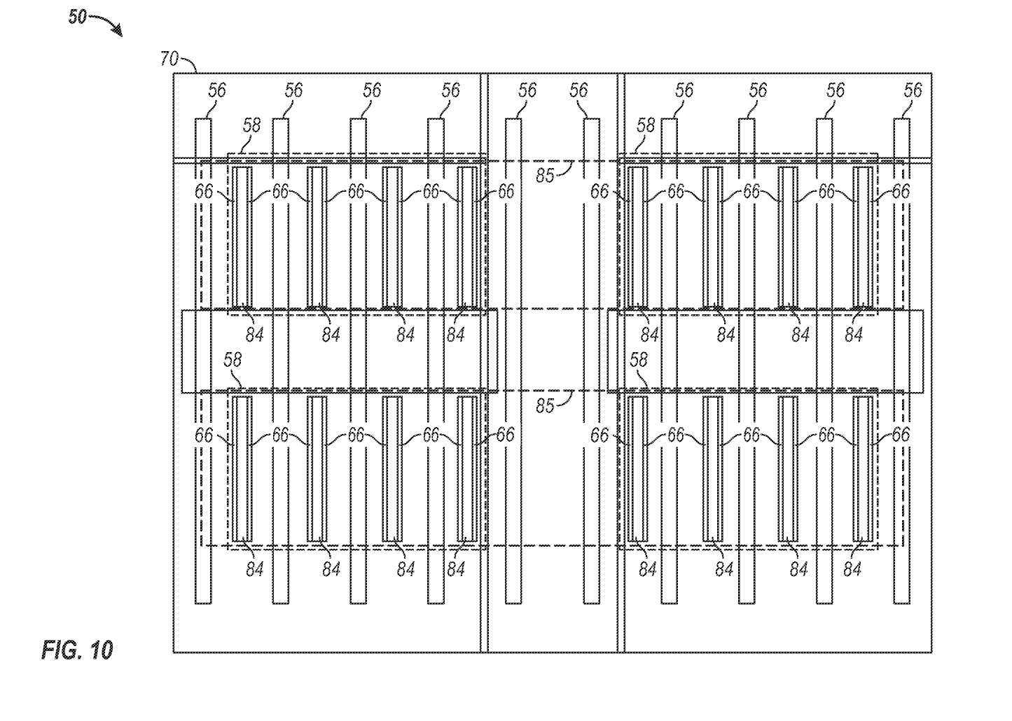

The pattern formed within mask stack 64 is now transferred to an upper region of PMD layer 60. A first etch may be performed to remove the portions of etch stop layer 66 exposed through etch mask openings 72 and thereby breakthrough layer 66, as shown in FIGS. 6 and 7. In embodiments wherein etch stop layer 66 is formed from a high-k dielectric material, a chlorine/CH_{X}F_{Y} etch chemistry may be employed. Further etching may then be carried-out to remove the upper regions of PMD layer 60 exposed through mask stack 64. Removal of PMD layer 60 may be accomplished by contacting integrated circuit 50 with a suitable-selective etchant, which stops on embedded gap fill bodies 62. For example, in embodiments wherein PMD layer 60 is composed of a nitride and gap fill bodies 62 are composed of an oxide, a wet etch utilizing a H₃PO₄ (hot phosphoric acid) chemistry or a dry etch utilizing a CHF₃/O₂ chemistry may be employed. As identified in FIG. 6, this pattern transfer process results in the formation of a series of self-aligned blind holes or non-penetrating trenches 80 extending from the upper surface of hardmask stack 64, through an upper portion of PMD layer 60, and to gap fill bodies 62. Trenches 80 may then be backfilled utilizing, for example, a flowable material (e.g., a flowable oxide); and subsequently polished back to nitride capping layer 68 to produce sacrificial plugs 82, as illustrated in FIG. 8. Sacrificial plugs 82 and the underlying gap fill bodies 62 are preferably formed from the same or like materials (e.g., the same gap fill oxide) to permit the subsequent removal utilizing a single etching process, as described below in conjunction with FIGS. 9 and 10. Sacrificial plugs 82 each extend to a different gap fill body 62 embedded PMD layer 60 to create a laterally-stepped or bottleneck-shaped structure 62, 82 embedded within mask stack 64 and PMD layer 60 and located between gate conductors 56, as generally shown in FIG. 8.

Advancing to FIGS. 9 and 10, a second lithographical patterning and etching process is next performed to carry the pattern formed within the upper region of PMD layer 60 downward through layer 60 and gap fill bodies 62 and thereby form fully-penetrating source/drain or TS trenches 84 extending to S/D regions 58. During the second lithographical patterning and etching process, a lithographical stack (not shown) may be formed over PMD layer 60 in the manner described above in conjunction with FIG. 3. As shown most clearly in FIG. 10, the non-illustrated lithographical stack may be imparted with relatively large, longitudinally-elongated openings or windows 85, which each extend across and are perpendicular to a different sub-set or grouping of trenches 80. The longitudinal axes of windows 85 may be substantially parallel with the minimum axis of the circuit layout. An etch may then be carried-out utilizing a chemistry that is highly selective to nitride over oxide (e.g., an C₅F₈/O₂ etch chemistry) to remove sacrificial plugs 82 (FIG. 8) and a central portion of gap fill bodies 62, while leaving intact the bulk of nitride capping layer 68. As noted above, sidewall spacers 78 may likewise be formed from an oxide and therefore also removed during the etching process to impart TS trenches 84 with a laterally enlarged mouth 86. A second nitride-selective etch may then be performed to remove the relatively thin regions of PMD layer 60 underlying the central portions of gap fill bodies 62 and thereby complete the formation of full-penetrating TS trenches 84. Any remaining portion of the lithographical stack may then stripped by, for example, ashing to yield the final structure shown in FIGS. 9 and 10.

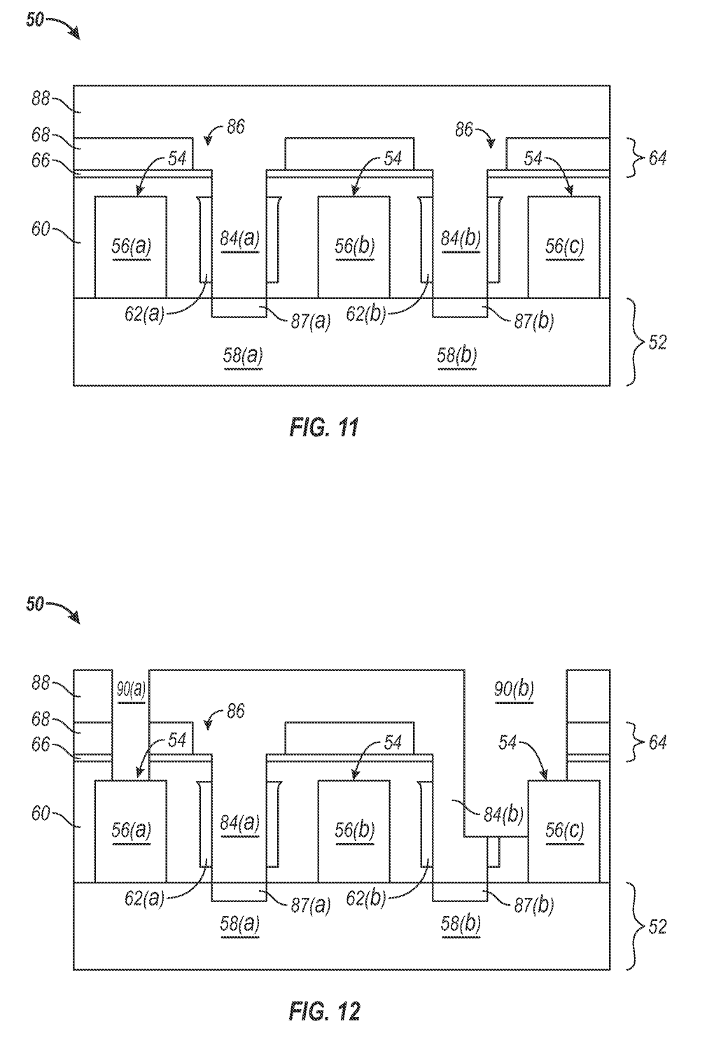

After the formation of TS trenches 84, a silicide-forming metal is deposited over the portions of substrate 52 exposed through trenches 84 and heated utilizing, for example, rapid thermal annealing (“RTA”) process to form silicide contact points 87 at the bottom of TS trenches 84 and within S/D regions 58, as shown in FIG. 11. Any silicide-forming metal that is not in contact with exposed silicon (e.g., the silicide-forming metal that is deposited on the upper surface of nitride capping layer 68 and the exposed ledges of etch stop layer 66) does not react during the RTA and can subsequently be removed via wet etching in a H₂O₂/H₂SO₄ or HNO₃/HCl solution. Suitable silicide-forming metals include cobalt and nickel, although other silicide-forming metals may be employed (e.g., rhenium, ruthenium, palladium, etc.). The silicide-forming metal can be deposited, for example, by sputtering to a thickness of about 5 nm to about 30 nm.

TS trenches 84 have thus been created within partially-fabricated integrated circuit 50. However, in contrast other known fabrication methods, TS trenches 84 are not metalized at this juncture in the fabrication process. Instead, TS trenches 84 are now backfilled with a backfill material, such as a flowable resist, to allow further patterning of partially-fabricated integrated circuit 50. For example, and with reference to FIG. 11, a flowable organic planarization material may be deposited over partially-completed integrated circuit 50 to backfill TS trenches 84 and to form an upper planar or unpatterned top layer 88 overlying nitride capping layer 68. As shown in FIG. 12, upper planar layer 88 may then be patterned to form gate conductor or CB opening 90 extending through layer 88 to each gate conductor 56 (the CB opening extending to gate conductor 56(b) is hidden from view in FIG. 12). In embodiments wherein integrated circuit 50 assumes the form of a densely-patterned SRAM cell, CB opening 90(b) may also extend laterally into backfilled TS trench 84(b) to enable the subsequent formation of a shared TS/CB contact, as described below in conjunction with FIG. 13.

After formation of CB openings 90, the backfilling of TS trenches 84, and the creation of upper planar layer 88, the previously-deposited backfill material may now be removed by, for example, ashing. A common metal fill is then carried-out to metalize now-empty TS trenches 84 and CB openings 90. In one implementation, tungsten is then deposited into TS trenches 84, into CB openings 90; over the upper surface of nitride capping layer 68, and over the exposed ledges of etch stop layer 66 by CVD or other deposition process; and the tungsten overburden is then removed by polishing by CMP polishing. With reference to FIG. 13, this results in the formation of a first CB contact 94(a) in ohmic contact with gate conductor 56(a), a second CB contact 94(b) in ohmic contact with gate conductor 56(c) and with a neighboring TS contact 96(b), a first TS contact 96(a) in ohmic contact with silicide contact point 87(a) of S/D region 58(a), and a second TS contact 96(b) in ohmic contact with silicide contact point 87(b) of S/D region 58(b) and with neighboring CB contact 94(b). Jointly, CB contact 94(b) and TS contact 96(b) form an electrically-bridged contact 94(b), 96(b). Although not shown in FIG. 13 for clarity, a barrier layer (e.g., tantalum nitride) and/or a seed layer (e.g., copper) may be deposited prior to metallization of contacts 94 and 96 utilizing, for example, a PVD or CVD process.

CB contacts 94 and TS contacts 96 extend through PMD layer 60 and overlying mask stack 64 to the upper surface of stack 64. Notably, CB contacts 94 and TS contacts 96 terminate at the same level or elevation above semiconductor substrate 52 and, specifically, within a plane that is substantially co-planar with the upper surface of capping layer 68 included within mask stack 64. Stated differently, CB contacts 94 and TS contacts 96 (collectively “device-level contacts 94, 96”) are confined to or are wholly contained within a device-contact level 99 formed immediately above semiconductor substrate 52. As indicated in FIG. 14, an interlevel dielectric (“ILD”) layer 98 (e.g., oxide) is next deposited over device-contact level 99 and, specifically, over the upper surface of mask stack 64 and the upper terminal ends of CB contacts 94 and TS contacts 96; patterned and etched to form interconnect (CA) contact openings through which CB contacts 94 and TS contacts 96 are exposed; and metalized. The metal overburden may then removed via CMP to yield unidirectional CA contacts 100 in a local interconnect level 102 above CB contacts 94 and TS contacts 96. As CA unidirectional contacts 100 are now formed entirely above and do not overlap in elevation with non-unidirectional CB contacts 94, the pattern density of local interconnect level 102 has been sufficiently decreased to enable the usage of copper during the metal fill of contacts 100. Conventional process steps may further be performed to complete integrated circuit 50 during BEOL processing. By fabricating the local interconnect lines (CA contacts 100) from low-resistance copper (as opposed to tungsten) the overall performance of integrated circuit 50 is enhanced. In addition, shifting CB contacts 94 to the device-contact level provides greater design freedom. The above-described exemplary fabrication method is also less complex as compared to current front-up manufacturing processes. It can also be seen in FIG. 13 that TS contact 96(a) has been imparted with a laterally-enlarged landing pad 97 to ensure proper alignment between TS contact 96(a) and overlying CA contact 100 and the creation of a low resistance electrical connection.

The foregoing has thus provided embodiments of a method for fabricating a high density integrated circuit, such as an SRAM cell, enabling the usage of copper in the formation of local interconnect lines (CA contacts) to improve overall device performance. In particular, in the above-described exemplary embodiment, the CA contacts and CB contacts were segregated between two different, non-overlapping levels or elevation ranges to decrease the pattern density at the CA local interconnect level and thereby allow compatibility with copper fill for critical dimensions of, for example, 20 nm and below. Additionally, embodiments of the above-described circuit fabrication method enabled the formation of a reliable electrical connection between the local interconnect lines and the conductive plugs (TS contacts) formed in contact with the electrically-active regions (RX) of the semiconductor substrate. Embodiments of the above-described method are especially well-suited for incorporation into various different types of gate last manufacturing processes, especially high-k/metal gate manufacturing processes.

While at least one exemplary embodiment has been presented in the foregoing Detailed Description, it should be appreciated that a vast number of variations exist. It should also be appreciated that the exemplary embodiment or exemplary embodiments are only examples, and are not intended to limit the scope, applicability, or configuration of the invention in any way. Rather, the foregoing Detailed Description will provide those skilled in the art with a convenient road map for implementing the exemplary embodiment or exemplary embodiments. It should be understood that various changes can be made in the function and arrangement of elements without departing from the scope of the invention, as set forth in the appended Claims and the legal equivalents thereof.

1. A method of manufacturing an integrated circuit, comprising:
producing a partially-fabricated integrated circuit, comprising:
a semiconductor substrate having source/drain regions; and
a plurality of transistors including a plurality of gate conductors formed over the semiconductor substrate and between the source/drain regions;
forming device-level contacts in ohmic contact with the gate conductors and with the source/drain regions, the device-level contacts terminating at substantially the same level above the semiconductor substrate; and
forming copper interconnect lines in a level above the device-level contacts and in ohmic contact therewith to locally interconnect the plurality of transistors.

2. A method according to claim 1 wherein forming copper interconnect lines comprises forming unidirectional copper interconnect lines in a level above the device-level contacts and in ohmic contact therewith to locally interconnect the plurality of transistors.

3. A method according to claim 2 wherein forming device-level contacts comprises forming non-unidirectional device-level contacts in ohmic contact with the gate conductors and with the source/drain regions.

4. A method according to claim 1 wherein producing a partially-fabricated integrated circuit further comprises depositing a pre-metal dielectric layer over the semiconductor substrate and the plurality of gate conductors.

5. A method according to claim 4 further comprising forming a mask stack over the pre-metal dielectric layer.

6. A method according to claim 5 wherein forming device-level contacts comprises:
creating source/drain contact openings extending through the mask stack, through the pre-metal dielectric layer, and to the source/drain regions; and
depositing a backfill material over the mask stack and into the source/drain contact openings to backfill the source/drain contact openings and to form an unpatterned top layer over the mask stack.

7. A method according to claim 6 further comprising forming silicide contact points within the areas of the source/drain regions exposed through the source/drain contact openings prior to depositing a backfill material over the mask stack and into the source/drain contact openings.

8. A method according to claim 6 further comprising patterning the unpatterned top layer, the mask stack, and the pre-metal dielectric layer to create gate conductor openings to the gate conductors.

9. A method according to claim 8 wherein patterning comprises patterning the unpatterned top layer to include at least one gate conductor opening extending laterally into at least one of the backfilled source/drain contact openings.

10. A method according to claim 8 further comprising:
removing the backfill material; and
depositing tungsten into the source/drain contact openings and the gate conductor openings to form the device-level contacts.

11. A method according to claim 10 further comprising:
forming an interlevel dielectric layer over the mask stack;
creating interconnect contact openings within the interlevel dielectric layer; and
filling the contact openings with copper to form the copper interconnect lines.

12. A method according to claim 6 wherein forming the mask stack comprises:
depositing an etch stop layer over the pre-metal dielectric layer; and
depositing a first capping layer over the etch stop layer.

13. A method according to claim 12 further comprising:
forming etch mask openings in at least the first capping layer; and
forming sidewall spacers within the etch mask openings to narrow the etch mask openings.

14. A method according to claim 13 further comprising etching a portion of the pre-metal dielectric layer through the narrowed etch mask openings to from non-penetrating trenches within the pre-metal dielectric layer.

15. A method according to claim 14 further comprising removing the sidewall spacers to impart at least one of the source/drain openings with a laterally-enlarged mouth.

16. A method according to claim 15 further comprising filling the laterally-enlarged mouth with tungsten to impart at least one of the device-level contacts in ohmic contact with the source/drain regions with an enlarged landing pad in ohmic contact with one of the copper interconnect lines.

17. A method according to claim 1 wherein the forming comprises forming copper interconnect lines in a level above the device-level contacts and in ohmic contact therewith to locally interconnect the plurality of transistors to produce a static random access memory cell.

18. A method of manufacturing an integrated circuit, comprising:
producing a partially-fabricated integrated circuit, comprising:
a semiconductor substrate having source/drain regions; and
a plurality of transistors including a plurality of gate conductors formed over the semiconductor substrate and between the source/drain regions;
forming device-level contacts in ohmic contact with the source/drain regions and to the gate conductors, the device-level contacts confined to a device-contact level formed immediately over the semiconductor substrate; and
forming copper interconnect lines over the device-level contacts and in ohmic contact therewith to locally interconnect the plurality of transistors, the copper interconnect lines confined to a local interconnect level overlying the device-contact level.

19. A method according to claim 18 wherein forming device-level contacts comprises forming a first device-level contact in ohmic contact with a first gate conductor included within the plurality of the gate conductors, and wherein forming non-overlapping copper interconnect lines comprises forming a copper interconnect line over and in ohmic contact with the first gate conductor.

20. A integrated circuit, comprising:
a semiconductor substrate having a plurality of source/drain regions;
a plurality of gate conductors formed over the semiconductor substrate;
a plurality of device-level contacts in ohmic contact with the gate conductors and with the source/drain regions, the device-level contacts terminating at substantially the same level above the semiconductor substrate; and
copper interconnect lines in a level above the device-level contacts and in ohmic contact therewith to locally interconnect the plurality of transistors.
